(19) United States
(12) Patent Application Publication
(10) Pub. No.: US 2025/0113690 A1
(43) Pub. Date: Apr. 3, 2025

(54) DISPLAY PANEL AND DISPLAY DEVICE

(71) Applicants: Hefei Visionox Technology Co., Ltd., Hefei (CN); KunShan Go-Visionox Opto-Electronics Co., Ltd., Kunshan (CN)

(72) Inventors: Guojun ZHANG, Kunshan (CN); Yang YANG, Kunshan (CN); Minghui WANG, Kunshan (CN); Lu ZHANG, Kunshan (CN); Mingwei GE, Kunshan (CN); Lixiong XU, Kunshan (CN); Mengyuan QU, Kunshan (CN); Xiujian ZHU, Kunshan (CN)

(73) Assignees: Hefei Visionox Technology Co., Ltd., Hefei (CN); KunShan Go-Visionox Opto-Electronics Co., Ltd., Kunshan (CN)

(21) Appl. No.: 18/967,680

(22) Filed: Dec. 4, 2024

Related U.S. Application Data
(63) Continuation of application No. PCT/CN2023/073959, filed on Jan. 31, 2023.

(30) Foreign Application Priority Data
Sep. 8, 2022 (CN) 202222394503.4

(51) Int. Cl. H10H 29/80; H10H 20/819; H10H 29/37

(52) U.S. Cl. CPC H10H 29/8321; H10H 20/819; H10H 29/37

(57) ABSTRACT

Provided are a display panel and a display device. The display panel includes isolation columns and a partition insulating layer. The partition insulating layer is disposed on at least one of a first side surface of the isolation column facing a hole region or a second side surface of the isolation column facing away from the hole region.

### CROSS-REFERENCE TO RELATED APPLICATIONS

This application is a continuation application of International Patent Application No. PCT/CN2023/073959, filed on Jan. 31, 2023, which claims priority to Chinese Patent Application No. 202222394503.4 filed on Sep. 8, 2022, all of which are hereby incorporated by reference in their entireties.

### TECHNICAL FIELD

Embodiments of the present application relate to the field of display technologies, for example, a display panel and a display device.

### BACKGROUND

With the development of display technologies, people have increasingly higher requirements for display quality.

In the related art, static electricity can enter a display region, causing black spots on the display and affecting the normal display of the display panel.

### SUMMARY

The present application provides a display panel and a display device.

In a first aspect, an embodiment of the present application provides a display panel. The display panel includes a display region and a non-display region.

The display panel includes a substrate, a first electrode layer, and at least an isolation column.

The first electrode layer is disposed on the substrate.

The at least an isolation column is disposed on the substrate, the at least an isolation column is located between the substrate and the first electrode layer, disposed in the non-display region, and configured to partition the first electrode layer.

One of the at least an isolation column at least includes an isolation portion, the isolation portion includes a side portion, and the side portion is provided with a partition insulating portion to insulate the side portion from the first electrode layer.

In a second aspect, an embodiment of the present application provides a display panel. The display panel includes a substrate, a first electrode layer disposed on the substrate, and at least an isolation column disposed on the substrate. The at least an isolation column is located between the substrate and the first electrode layer and is disposed in the non-display region, an isolation column of the at least an isolation column at least includes an isolation portion, the isolation portion includes a side portion. The first electrode layer includes a first portion and a second portion which are partitioned by the at least an isolation column. The first portion is located at one side of the at least an isolation column facing away from the substrate, and the second portion is adjacent to the side portion in a direction from a display region of the display panel to a non-display region of the display panel. The side portion is provided with a partition insulating portion. The second portion is insulated from the side portion.

In a third aspect, an embodiment of the present application further provides a display device. The display device includes the display panel described in the first aspect.

### BRIEF DESCRIPTION OF DRAWINGS

FIG. 1 is a structural diagram of a display panel;

FIG. 2 is a plan diagram of a display panel according to an embodiment of the present application;

FIG. 3 is a sectional diagram of a display panel according to an embodiment of the present application;

FIG. 4 is a sectional diagram of another display panel according to an embodiment of the present application;

FIG. 5 is a sectional diagram of another display panel according to an embodiment of the present application;

FIG. 6 is a sectional diagram of another display panel according to an embodiment of the present application;

FIG. 7 is a sectional diagram of another display panel according to an embodiment of the present application;

FIG. 8 is a flowchart of a preparation method for a display panel according to an embodiment of the present application;

FIG. 9 is a schematic diagram of a middle structure of a display panel after isolation column limiting positions are formed according to an embodiment of the present application;

FIG. 10 is a schematic diagram of a middle structure of a display panel after isolation columns are formed according to an embodiment of the present application;

FIG. 11 is a flowchart of another preparation method for a display panel according to an embodiment of the present application; and

FIG. 12 is a schematic diagram of a middle structure of a display panel after a protective layer material is formed according to an embodiment of the present application.

### DETAILED DESCRIPTION

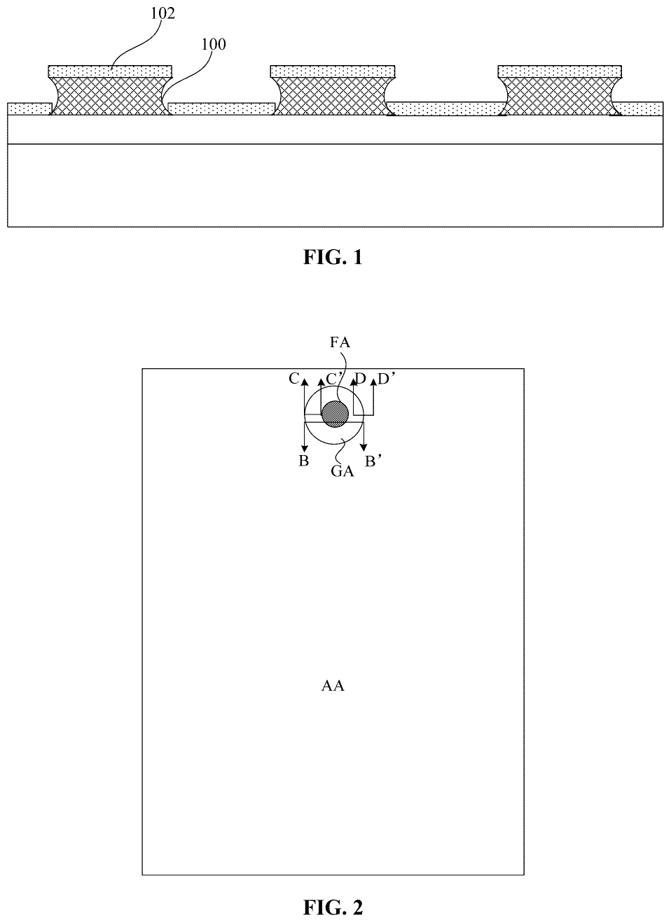

As mentioned in the BACKGROUND, static electricity can enter a display region, causing black spots on the display and affecting the normal display of the display panel. Through research, the applicant found that the reason for the preceding case is that the material of an isolation column in a non-display region is generally a metal material. Referring to FIG. 1, an isolation column 100 in the display panel is generally in the shape of “I” as shown in FIG. 1. After the isolation column 100 is formed, a common conductive layer, such as a cathode layer 102 of a light-emitting diode in the display panel, needs to be formed above the isolation column 100. The formed cathode layer is generally made as an entire surface. The cathode layer 102 between isolation columns 100 connects with the isolation columns 100 to form a lateral connection path. Static electricity enters a display region through the lateral connection path, causing damage to light-emitting diodes in the display region and resulting in the generation of black spots on the display.

Based on the preceding reason, an embodiment of the present application provides a display panel. The display panel includes a display region and a non-display region.

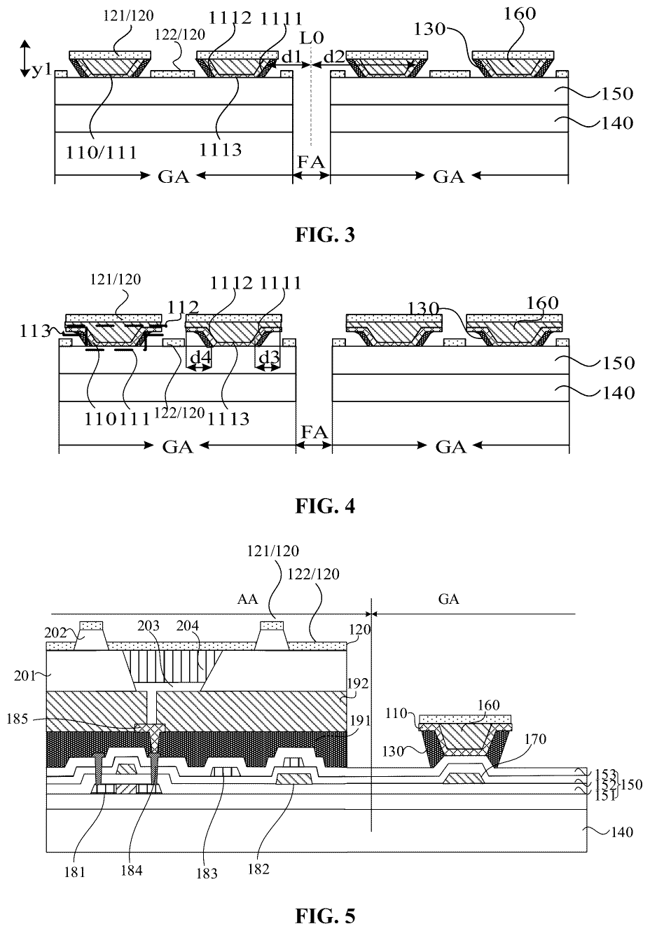

For example, FIG. 2 is a plan diagram of a display panel according to an embodiment of the present application. FIG. 3 is a sectional diagram of a display panel according to an embodiment of the present application. FIG. 3 may be obtained correspondingly by cutting along a section line BB′ in FIG. 2. Referring to FIGS. 2 and 3, the display panel includes a display region AA, a hole region FA, and a non-display region GA between the display region AA and the hole region FA. The non-display region GA surrounds at least part of the hole region FA.

The display panel includes a substrate 140 and a first electrode layer 120 disposed on the substrate 140. One or more isolation columns 110 are disposed on the substrate 140 in the non-display region GA. The isolation columns 110 are located between the substrate 140 and the first electrode layer 120. The first electrode layer 120 is partitioned or separated by the one or more isolation columns 110.

The isolation column 110 includes at least an isolation portion 111. The isolation portion 111 includes a side portion provided with a partition insulating portion 130. For example, the side portion includes a first side portion 1111 facing away from the display region AA and a second side portion 1112 facing the display region AA. At least one of the first side portion 1111 or the second side portion 1112 is provided with the partition insulating portion 130 to insulate the side portion from the first electrode layer 120.

In one or more embodiments of the present application, referring to FIG. 3 and FIG. 4, the first electrode layer 120 is partitioned/separated into a first portion 121 and a second portion 122 by the isolation column 110. The first portion 121 is located at one side of the isolation column 110 facing away from the substrate 140. The second portion 122 is adjacent to the first side portion 1111 or the second side portion 1112 in a direction from the display region AA to the non-display region GA. The second portion 122 is insulated from the first side portion 1111 or the second side portion 1112 of the isolation column 110.

The substrate 140 can provide buffering, protection, or support for a display device. The substrate 140 may be a flexible substrate 140, and the material of the flexible substrate 140 may be polyimide (PI), polyethylene naphthalate (PEN), polyethylene terephthalate (PET), or a mixture of the preceding materials. The substrate 140 may be a hard substrate 140 made of glass or other materials. When the substrate 140 is a flexible substrate, the display panel in this embodiment can be applied in a foldable display device.

For example, the first electrode layer 120 is the cathode layer of the light-emitting diode in the display panel. When the display panel is manufactured, the first electrode layer 120 is formed as an entire surface. For example, the entire first electrode layer 120 may be formed through a sputtering process. For example, the light-emitting diode is an organic light-emitting diode, and a light-emitting material layer is further included on a side of the first electrode layer 120 facing the substrate 140.

The display region AA of the display panel may be provided with pixel circuits and light-emitting diodes to implement the display function. For example, the display panel further includes the hole region FA, the non-display region GA surrounds at least part of the hole region FA, and the isolation columns 110 surround the hole region FA. The hole region FA may be provided with functional components such as a camera and a sensor to implement the camera or other sensing functions of the display panel. The opening provided in the hole region FA may be a through hole or a blind hole, which is not specifically limited in this embodiment.

To avoid the case where the isolation columns 110 cannot completely partition the first electrode layer 120, in this embodiment, the display panel further includes the partition insulating portion 130, where the material of the partition insulating portion 130 may be an organic material or an inorganic material, which is not specifically limited in this embodiment. The partition insulating portion 130 is disposed on the first side portion 1111 of the isolation portion 111 facing the hole region FA and/or the second side portion 1112 of the isolation portion 111 facing away from the hole region FA so that the first electrode layer 120 cannot be in contact with the isolation portion 111 at the first side portion 1111 or the second side portion 1112, thereby completely partitioning the first electrode layer 120 and avoiding the following: when the isolation portion 111 is made of a conductive material, the first electrode layer 120 is in contact with the isolation portion 111 to form a lateral conductive path. That is, the partition insulating portion 130 is disposed on the first side portion 1111 of the isolation portion 111 facing the hole region FA and/or the second side portion 1112 of the isolation portion 111 facing away from the hole region FA so that a lateral conductive path (the connection direction between the hole region FA the display region AA) cannot be formed in the non-display region GA; in this manner, even if static electricity is introduced into the hole region FA, the static electricity cannot enter the display region AA through the non-display region GA, thereby avoiding the generation of black spots on the display.

With continued reference to FIG. 3, for example, the display panel further includes an interlayer insulating layer 150 disposed between the substrate 140 and the isolation columns 110. The interlayer insulating layer 150 may be an insulating layer inherent in the preparation process of the display panel, for example, an insulating layer between multiple metal layers in the display panel.

In the display panel of this embodiment, the display panel includes the isolation columns and the partition insulating portions, and the partition insulating portion is disposed on at least one of the first side portion of the isolation column facing the hole region or the second side portion of the isolation column facing away from the hole region so that the first electrode layer cannot be in contact with the isolation column on at least one of the first side portion or the second side portion, the first electrode layer is completely partitioned, and a conductive path cannot be formed in the non-display region; in this manner, even if static electricity is introduced, the static electricity cannot enter the display region through the non-display region, thereby avoiding the generation of black spots on the display.

Based on the preceding technical solution, in a first direction y1 from the first electrode layer 120 to the substrate 140, the linear distance between the first side portion 1111 and the hole region FA at least partially gradually increases, and/or the linear distance between the second side portion 1112 and the hole region FA at least partially gradually decreases.

FIG. 3 schematically shows the case where in the first direction y1, the linear distance (the first linear distance d1) between the first side portion 1111 and the hole region FA continuously increases, and in the first direction y1, the linear distance (the second linear distance d2) between the second side portion 1112 and the hole region FA at least partially continuously decreases.

In the first direction y1, the linear distance between the first side portion 1111 and the hole region FA at least partially continuously increases, which means that in the first direction y1, that is, in the height direction of the isolation column 110, from top to bottom (where the up and bottom are relative concepts, and the up is closer to a light-emitting surface of the display panel than the bottom), the linear distance between the first side portion 1111 and the hole region FA gradually increases instead of suddenly increasing. The gradual increase in linear distance means that the absolute value of the difference between the linear distance between the first position of the first side portion 1111 and the hole region FA, and, the linear distance between the second position of the first side portion 1111 and the hole region is less than a set threshold. The first position and the second position are two adjacent positions on the first side portion 1111 from top to bottom. The shape of the isolation column 110 may reflect that in the cross section of the isolation column 110 in the thickness direction of the display panel, at least part of the side facing the hole region FA is a straight line with a bevel or a smooth arc.

In the first direction y1, the linear distance between the second side portion 1112 and the hole region FA at least partially continuously decreases, which means that in the first direction y1, that is, in the height direction of the isolation column 110, from top to bottom, the linear distance between the second side portion 1112 and the hole region FA gradually decreases instead of suddenly decreasing. The gradual decrease in linear distance means that the absolute value of the difference between the linear distance between the third position of the second side portion 1112 and the hole region FA, and the linear distance between the fourth position of the second side portion 1112 and the hole region is less than a set threshold. The third position and the fourth position are two adjacent positions on the second side portion 1112 from top to bottom. The shape of the isolation column 110 may reflect that in the cross section of the isolation column 110 in the thickness direction of the display panel, at least part of the side facing away from the hole region FA is a straight line with a bevel or a smooth arc.

For example, the distance between any position on the side portion and the hole region FA may be the distance between the position on the side portion and a centerline L0 of the hole region FA.

In the first direction y1 from the first electrode layer 120 to the substrate 140, the linear distance between the first side portion 1111 and the hole region FA at least partially gradually increases, and/or the linear distance between the second side portion 1112 and the hole region FA at least partially gradually decreases, which is conducive to the following: the common conductive layer 120 is partitioned on a side portion of the isolation column 110 facing the hole region FA, and/or the common conductive layer 120 is partitioned on a side portion of the isolation column 110 facing away from the hole region FA.

For example, the isolation portion 111 has a structure recessed in the first direction y1.

For example, the thickness of the film during film formation is generally uniform. Therefore, after the partition insulating portion 130 is patterned to form an isolation column limiting position (the isolation column limiting position is in the shape of a groove), the isolation column 110 is formed at the isolation column limiting position, and the isolation column 110 includes the isolation portion 111 with a structure recessed in the first direction y1.

With continued reference to FIG. 3, for example, the isolation portion 111 further includes a bottom 1113. Since the isolation portion 111 has a structure recessed in the first direction, the isolation portion 111 includes an accommodation space surrounded by at least the bottom 1113, the first side portion 1111, and the second side portion 1112. A side of the bottom 1113 facing away from the display region is connected to the first side portion 1111, and a side of the bottom 1113 facing the display region is connected to the second side portion 1112.

For example, the cross section of the accommodation space in the stacking direction y1 of the display panel is an inverted trapezoid.

The inverted trapezoid may be an isosceles trapezoid, a right trapezoid, a non-isosceles trapezoid, or a non-right trapezoid, which is not specifically limited in this embodiment. The cross section of the accommodation space in the stacking direction y1 of the display panel is an inverted trapezoid so that when the first electrode layer 120 is formed above the isolation column 110, the first electrode layer 120 is more easily partitioned by the isolation portion 111.

It is to be noted that in the embodiment of the present application, the isolation column may be in another shape, such as the shape of “I” shown in FIG. 1, which is not specifically limited in the present application.

FIG. 4 is a sectional diagram of another display panel according to an embodiment of the present application. FIG. 4 may be obtained correspondingly by cutting along the section line BB′ in FIG. 2. For example, the isolation column 110 further includes a first edge portion 112 and a second edge portion 113. The first edge portion 112 is connected to an end of the first side portion 1111 facing away from the substrate 140, and the second edge portion 113 is connected to an end of the second side portion 1112 facing away from the substrate 140.

The isolation column 110 includes the first edge portion 112 and the second edge portion 113 so that when the first electrode layer 120 is formed, the first electrode layer 120 can be blocked by the first edge portion 112 and the second edge portion 113, the first electrode layer 120 cannot be formed at positions corresponding to the first edge portion 112 and the second edge portion 113 on the interlayer insulating layer 150, it is more difficult for the first electrode layer 120 to be in contact with the isolation column 110, a lateral conductive path is difficult to form, and it is more difficult for static electricity to enter the display region AA through the non-display region GA, thereby avoiding the generation of black spots on the display. Moreover, the following can be avoided: a sharp corner structure is formed when the isolation column 110 includes only the isolation portion 111, causing subsequent film breakage and affecting encapsulation reliability. In this solution, the isolation column 110 is further provided with the first edge portion 112 and the second edge portion 113 that have a relatively horizontal structure so that during the subsequent encapsulation step, the formed film of an encapsulation layer is relatively flat and uniform, which is more conducive to the film formation of the encapsulation layer.

With continued reference to FIG. 4, for example, the orthographic projection of the first edge portion 112 and the first side portion 1111 on the substrate 140 is a first orthographic projection, and the distance d3 between the inner and outer contours of the first orthographic projection is greater than or equal to 3 microns; and/or the orthographic projection of the second edge portion 113 and the second side portion 1112 on the substrate 140 is a second orthographic projection, and the distance d4 between the inner and outer contours of the second orthographic projection is greater than or equal to 3 microns. Through the preceding dimension limitation, a sharp corner structure can be effectively prevented from being formed at the position of the isolation column 110 facing the first electrode layer 120, and it is ensured that the first edge portion 112 and the second edge portion 113 form a relatively horizontal structure so that during the subsequent encapsulation step, the formed film of an encapsulation layer is relatively flat and uniform, which is more conducive to the film formation of the encapsulation layer.

For example, the orthographic projection of the partition insulating portion 130 on the substrate 140 is located within the orthographic projection of the isolation column 110 on the substrate 140, thereby avoiding the following case: when the orthographic projection of the partition insulating portion 130 on the substrate is located outside the orthographic projection of the isolation column 110 on the substrate 140, the first electrode layer 120 between adjacent isolation columns 110 is raised, and thus the first electrode layer 120 cannot be partitioned.

FIG. 5 is a sectional diagram of another display panel according to an embodiment of the present application. FIG. 5 may be obtained correspondingly by cutting along a section line DD′ in FIG. 2. Referring to FIGS. 3 to 5, for example, the display panel further includes a protective layer 160 located at least within the accommodation space.

For example, the protective layer 160 is located at least within the accommodation space so that the protective layer 160 at least protects the isolation portion 111.

In the manufacturing process of the display panel, the formation process of the protective layer 160 requires first forming a protective layer material and then patterning the protective layer material, where the protective layer material may at least cover the surface of the isolation portion 110 exposed to the partition insulating portion 130, thereby preventing the surface of a side of the isolation portion 111 facing away from the substrate 100 from being etched in the subsequent preparation process and ensuring the isolation effect of the isolation portion 111 on the first electrode layer 120.

With continued reference to FIG. 5, in another example embodiment of the present application, the protective layer 160 further covers a side of the first edge portion 112 facing away from the substrate 140 and/or a side of the second edge portion 113 facing away from the substrate 140 so that the protective layer 160 can protect the first edge portion 112 and/or the second edge portion 113.

With continued reference to FIG. 5, for example, the display panel further includes multiple insulating layers located in the display region AA and stacked between the substrate 140 and the first electrode layer 120, the multiple insulating layers include a first planarization layer 191, a second planarization layer 192, a pixel defining layer 201, and support columns 202 that are stacked in a direction from the substrate 140 to the first electrode layer 120.

The partition insulating portion 130 is disposed in the same layer as any one of the multiple insulating layers. For example, the partition insulating portion 130 is disposed in the same layer as any one of the first planarization layer 191, the pixel defining layer 201, the second planarization layer 192, or the support columns 202.

For example, in the display region, the display panel further includes multiple metal layers stacked between the substrate 140 and the first electrode layer 120. The first planarization layer 191 may be disposed on a side of at least one metal layer facing away from the substrate 140, and the surface of a side of the first planarization layer 191 facing away from the substrate 140 is flat, thereby facilitating subsequent manufacturing processes. For example, the material of the first planarization layer 191 may be an organic material.

The second planarization layer 192 is closer to the first electrode layer 120 than the first planarization layer 191. For example, the display panel further includes a second electrode layer 203 disposed on a side of the first electrode layer 120 facing the substrate 140, and a light-emitting material layer 204 is located between the first electrode layer 120 and the second electrode layer 203. The second planarization layer 192 may be disposed in the stacked metal layers and located between the metal layer closest to the second electrode layer in the stacked metal layers and the second electrode layer. Since the second planarization layer 192 is relatively thick, the surface of the second planarization layer 192 facing the first electrode layer 120 and the second electrode layer 203 is relatively flat so that the surface of the second electrode layer 203 formed on the second planarization layer 192 is also relatively flat, thereby making the light-emitting diode have a better light-emitting effect. For example, the material of the second planarization layer 192 may be an organic material. In this embodiment, the protective layer 160 and the second planarization layer 192 are in the same layer, and the material of the protective layer 160 may be the same as the material of the second planarization layer 192 so that the protective layer 160 and the second planarization layer 192 are formed in the same process step without additional process steps during the preparation process of the display panel, thereby simplifying the preparation process of the display panel.

The pixel defining layer 201 may include multiple openings in which the light-emitting material layer of the light-emitting diodes may be disposed, and each opening may correspond to one light-emitting diode. For example, the material of the pixel defining layer 201 is an organic material.

The support columns 202 may be used for supporting the mask when the first electrode layer 120 is manufactured. For example, the material of the support columns 202 is an organic material.

In this embodiment, the partition insulating portion 130 is disposed in the same layer as one of the first planarization layer 191, the pixel defining layer 201, the second planarization layer 192, or the support columns 202. Correspondingly, the material of the partition insulating portion 130 may be the same as the material of one of the first planarization layer 191, the pixel defining layer 201, the second planarization layer 192, or the support columns 202 so that the partition insulating portion 130 and one of the first planarization layer 191, the pixel defining layer 201, the second planarization layer 192, or the support columns 202 are made in the same process step without additional process steps, thereby simplifying the preparation process of the display panel.

As described in the preceding embodiments, the display panel includes the encapsulation layer located on a side of the isolation columns facing away from the substrate.

Through research, the applicant found that, after multiple film structures of the display panel are formed, holes need to be punched in the display panel; when holes are punched in the display panel, the encapsulation layer is prone to cracking at the punching position; the surface of the encapsulation layer facing the light-emitting surface of the display panel has a planar structure or has relatively small undulations, making cracks in the hole region easy to extend to the non-display region and the display region and affecting the performance of the display panel.

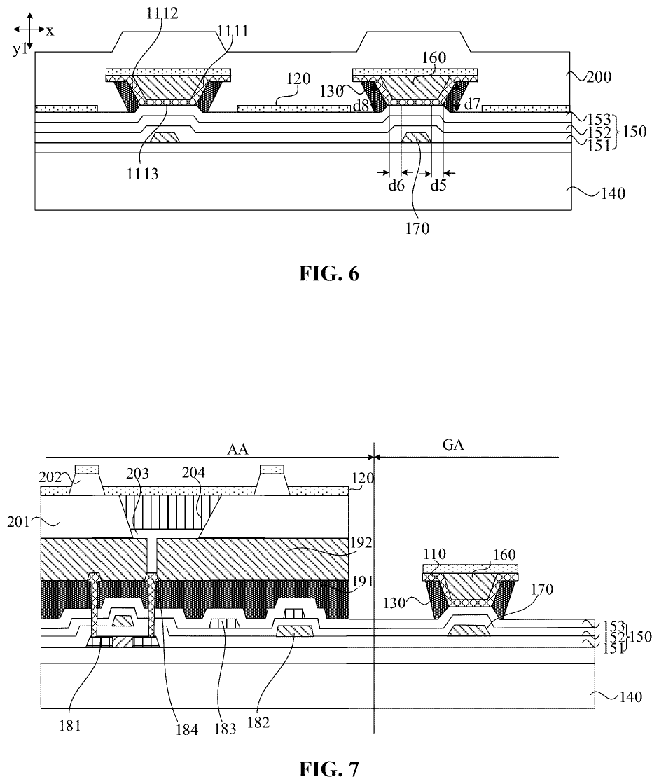

To improve the case where cracks in the hole region easily extend to the non-display region and the display region, the embodiment of the present application provides another display panel. FIG. 6 is a sectional diagram of another display panel according to an embodiment of the present application. The sectional diagram may be obtained correspondingly by cutting along CC′ in FIG. 2. Referring to FIG. 6, for example, the display panel further includes a raising block 170 disposed between the substrate 140 and the isolation column 110. The orthographic projection of the raising block 170 on the substrate 140 is located within the orthographic projection of the bottom 1113 on the substrate 140.

For example, the display panel is configured to further include a raising block 170, which is equivalent to increasing the height between the isolation column 110 and the substrate 140. In this manner, during the film formation of an encapsulation layer 200 in a side of the isolation column 110 away from the substrate 140, a raised structure is easily formed at the position of the isolation column 110 so that the surface of the finally formed encapsulation layer shows a relatively large undulating shape, which is conducive to blocking the extension of cracks.

For example, if the orthographic projection of the raising block 170 on the substrate 140 is within the orthographic projection of the bottom 1113 on the substrate 140, then in the cross section in the thickness direction y1 of the display panel, in the connection direction x between the non-display region GA and the hole region FA, the dimension of the bottom 1113 of the isolation column 110 is greater than the dimension of the raising block 170. The orthographic projection of the raising block 170 on the substrate 140 is located within the orthographic projection of the bottom 1113 on the substrate 140, which is equivalent to a relative increase in height difference between the isolation column 110 and the substrate 140, which is conducive to the partition of the first electrode layer 120. At the same time, since the height difference between the isolation column 110 and the substrate 140 increases, the surface of the finally formed encapsulation layer 200 shows a relatively large undulating shape, which is conducive to blocking the extension of cracks.

With continued reference to FIG. 6, for example, the interlayer insulating layer 150 is disposed between the raising block 170 and the isolation column 110, where the distance between at least part of the contour of the orthographic projection of the raising block 170 on the substrate 140 and the outer contour of the orthographic projection of the bottom 1113 on the substrate 140 is less than or equal to twice the thickness of the interlayer insulating layer 150.

For example, the distance d5 between the orthographic projection of the edge of the raising block 170 facing the hole region on the substrate 140 and the orthographic projection of the edge of the bottom 1113 facing the hole region on the substrate 140 is less than or equal to twice the thickness of the interlayer insulating layer 150.

Moreover/alternatively, the distance d6 between the orthographic projection of the edge of the raising block 170 facing away from the hole region on the substrate 140 and the orthographic projection of the edge of the bottom 1113 facing away from the hole region FA on the substrate 140 is less than or equal to twice the thickness of the interlayer insulating layer 150. In this manner, it is ensured that the dimension of the raising block 170 is not too small, and the raising block 170 can achieve the effect of increasing the height between the isolation column 110 and the substrate 140.

With continued reference to FIG. 6, for example, the maximum distance d7 between the first side portion 1111 and the interlayer insulating layer 150 in the stacking direction y1 of the display panel is greater than or equal to 0.6 microns and less than or equal to 3 microns, and/or the maximum distance d8 between the second side portion 1112 and the interlayer insulating layer 150 in the stacking direction y1 of the display panel is greater than or equal to 0.6 microns and less than or equal to 3 microns. It is further ensured that the height between the isolation column 110 and the substrate 140 is large enough, and it is ensured that a crack blocking structure can be formed during the film formation of the encapsulation layer 200, which is conducive to blocking the extension of cracks in the encapsulation layer 200.

FIG. 7 is a structural diagram of another display panel according to an embodiment of the present application. The sectional diagram may be obtained correspondingly by cutting along DD′ in FIG. 2. Referring to FIG. 7, for example, a gate layer 182, a capacitor layer 183, and a source-drain layer 184 are stacked; and an active layer 181 is located on a side of the gate layer 182 facing the substrate 140 or facing away from the substrate 140; where the raising block 170 is in the same layer as any one of the active layer 181, the gate layer 182, the capacitor layer 183, or the source-drain layer 184, and the isolation column 110 is located on a side of the raising block 170 facing away from the substrate 140.

For example, pixel circuits are disposed in the display region AA, and the pixel circuit includes a thin-film transistor and a capacitor. The conductive channel of the thin-film transistor may be disposed in the active layer 181, the gate of the thin-film transistor and one plate of the capacitor may be disposed in the gate layer 182, and the other plate of the capacitor may be disposed in the capacitor layer 183. The source electrode and drain electrode of the thin-film transistor may be disposed in the source-drain layer. When the raising block 170 is in the same layer as any of the active layer 181, the gate layer 182, the capacitor layer 183, or the source-drain layer 184, the material of the raising block 170 is the same as the material of the film in the same layer as the raising block 170 so that the raising block 170 can be manufactured in the same process as the film structure of the display region AA, and the isolation column 110 can be raised without adding an additional film structure in the display panel, thereby ensuring that the preparation process of the display panel is relatively simplified and the film structure is also relatively simplified.

In an example embodiment of the present application, the isolation column 110 is in the same layer as one of the gate layer 182, the capacitor layer 183, or the source-drain layer 184, and the isolation column 110 and the raising block 170 are located in different layers so that the isolation column 110 can be formed in one process with the gate layer 182, the capacitor layer 183, or the source-drain layer 184, and thus the preparation process of the display panel is relatively simplified.

In another example embodiment of the present application, the display region of the display panel further includes a metal layer on a side of the source-drain layer facing away from the substrate, for example, the structure shown in FIG. 5. Referring to FIG. 5, for example, the isolation column 110 is in the same layer as the metal layer located on the side of the source-drain layer 184 facing away from the substrate 140.

With continued reference to FIG. 5, in an example embodiment of the present application, the display panel further includes the second electrode layer 203 and the light-emitting material layer 204 that are stacked between the source-drain layer 184 and the first electrode layer 120, and the source-drain layer 184 and the second electrode layer 203 are electrically connected through a via connecting portion 185. In this embodiment, the metal layer on the side of the source-drain layer 184 facing away from the substrate 140 is the via connecting portion 185, and the isolation column 110 and the via connecting portion 185 are located in the same layer.

For example, the isolation column 110 and the via connecting portion 185 are disposed in the same layer, and the material of the isolation column 110 may be same as the material of the via connecting portion 185. For example, the material of the via connecting portion 185 is titanium-aluminum-titanium (the via connecting portion 185 includes a three-layer structure, in which the materials of the films on two sides are both titanium and the material of the middle film is aluminum). The isolation column 110 and the via connecting portion 185 are disposed in the same layer so that the isolation column 110 can be manufactured in the same process as the film structure of the display region AA, and the isolation column 110 can be prepared without adding an additional film structure to the display panel, thereby ensuring that the preparation process of the display panel is relatively simplified and the film structure is also relatively simplified.

With continued reference to FIGS. 5 to 7, for example, the interlayer insulating layer 150 may include a first insulating layer 151, a second insulating layer 152, and a third insulating layer 153.

As mentioned above, for example, the display panel further includes the encapsulation layer 200. The structure of the encapsulation layer 200 is schematically shown in FIG. 6 and is not shown in the structural diagrams of other structures in the display panel. The encapsulation layer 200 is located on a side of the first electrode layer 120 facing away from the isolation column 110.

In the display region, the display panel may include an organic encapsulation layer and an inorganic encapsulation layer. For example, the display region may include two inorganic encapsulation layers and one organic encapsulation layer, where the organic encapsulation layer is located between the two inorganic encapsulation layers. The non-display region may include two inorganic encapsulation layers. The arrangement of the encapsulation layer (herein referred to as the organic encapsulation layer and the inorganic encapsulation layer) in the display region and the non-display region can make it difficult for water and oxygen to invade the display panel, thereby extending the service life of the display panel.

Based on the preceding multiple technical solutions, the thickness of the partition insulating portion is greater than the thickness of the first electrode layer. In this manner, the first electrode layer cannot cross the partition insulating portion to be in contact with the isolation portion, thereby preventing a conductive path from the non-display region to the display region from being formed when the isolation portion is made of a conductive material, ensuring that the first electrode layer can be partitioned by the isolation portion and the partition insulating portion during film formation, and avoiding the formation of a lateral conductive path.

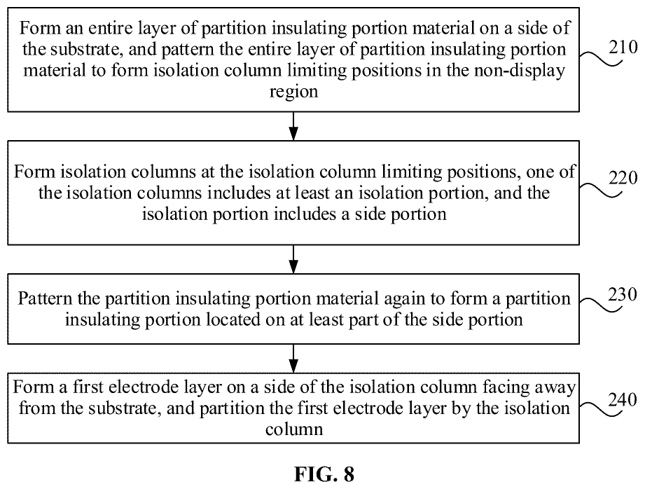

The present application further provides a preparation method for a display panel, where the display panel includes a display region, a hole region, and a non-display region between the display region and the hole region, and the non-display region surrounds at least part of the hole region. FIG. 8 is a flowchart of a preparation method for a display panel according to an embodiment of the present application. Referring to FIG. 8, the preparation method for a display panel includes the steps described below.

In step 210, an entire layer of partition insulating portion material is formed on a side of the substrate, and the entire layer of partition insulating portion material is patterned to form isolation column limiting positions in the non-display region.

The isolation column limiting position may be annular. When punching is performed later, a hole is punched at least part of the position surrounded by the isolation column limiting position to form the hole region. The display panel includes the display region and the non-display region, where the non-display region surrounds at least part of the hole region, and the isolation column limiting position surrounds the hole region.

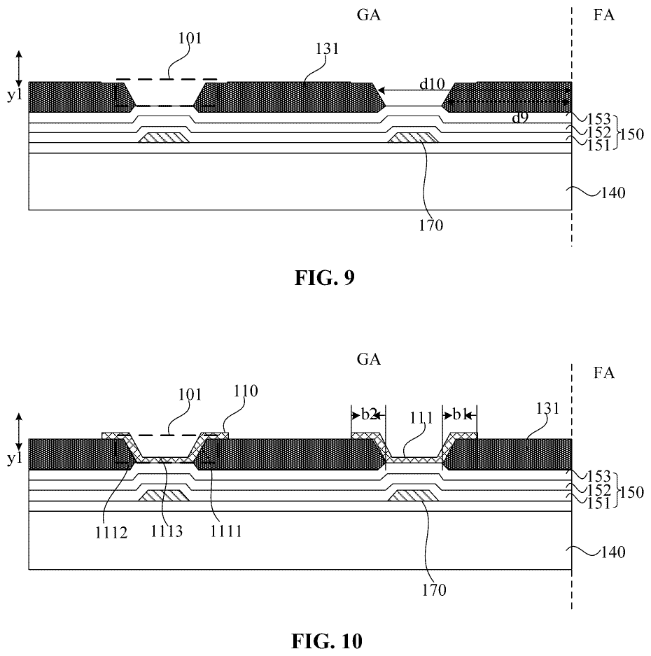

FIG. 9 is a schematic diagram of a middle structure of a display panel after isolation column limiting positions are formed. Referring to FIG. 9, in the thickness direction y1 of the display panel, the linear distance (the third linear distance d9) between the side portion of the isolation column limiting position 101 facing the hole region FA and the hole region FA at least partially continuously increases; and/or from the surface of the partition insulating portion material facing the light-emitting surface of the display panel to the surface of the partition insulating portion material facing away from the light-emitting surface of the display panel, the linear distance (the fourth linear distance d10) between the side portion of the isolation column limiting position facing away from the hole region FA and the hole region FA at least partially continuously decreases.

The partition insulating portion material may be an organic material. The film formed by the organic material is thicker than the film formed by the inorganic material so that the formed isolation column limiting position can have a greater depth. Correspondingly, the height of the isolation column 110 may be relatively large, which is conducive to achieving that the isolation column 110 partitions the second electrode layer 120. Moreover, the height of the isolation column 110 is relatively large, which is conducive to blocking the extension of cracks.

In step 220, isolation columns are formed at the isolation column limiting positions, where one of the isolation columns at least includes an isolation portion, and the isolation portion includes a side portion.

The side portion includes a first side portion facing the hole region and a second side portion facing away from the hole region, that is, the side portion includes a first side portion facing away from the display region and a second side portion facing the display region.

FIG. 10 is a schematic diagram of a middle structure of a display panel after isolation columns are formed. The isolation column 110 is formed at the isolation column limiting position. In the thickness direction y1 of the display panel, the linear distance between the side portion of the isolation column limiting position 101 facing the hole region FA and the hole region FA at least partially continuously increases so that in the thickness direction y1 of the display panel, the linear distance between the first side portion and the hole region FA at least partially continuously increases, which is conducive to partitioning the first electrode layer at the first side portion of the isolation column 110; or in the thickness direction y1 of the display panel, the linear distance between the side portion of the isolating column limiting position facing away from the hole region FA and the hole region FA at least partially continuously decreases so that in the thickness direction y1 of the display panel, the linear distance between the second side portion and the hole region FA at least partially continuously decreases, which is conducive partitioning the first electrode layer at the second side portion of the isolation column 110.

For example, step 220 further includes forming the isolation portion inside the isolation column limiting position and forming a first edge portion and a second edge portion at the edge of the isolation column limiting position, the first edge portion is connected to an end of the first side portion facing away from the substrate, and the second edge portion is connected to an end of the second side portion facing away from the substrate. The overlapping dimension b1 between the orthographic projection of the first edge portion and the first side portion in the thickness direction y1 of the display panel and the orthographic projection of the partition insulating portion material in the thickness direction y1 of the display panel is greater than or equal to 3 microns, thereby ensuring that the first edge portion has a sufficient dimension. The overlapping dimension b2 between the orthographic projection of the second edge portion and the second side portion in the thickness direction y1 of the display panel and the orthographic projection of the partition insulating portion material in the thickness direction y1 of the display panel is greater than or equal to 3 microns so that the isolation column can form an eaves structure, which is more conducive to partitioning the first electrode layer by the isolation column partitions.

In step 230, the partition insulating portion material is patterned again to form a partition insulating portion located on at least part of the side portion.

In step 240, a first electrode layer is formed on a side of the isolation column facing away from the substrate, and the first electrode layer is partitioned by the isolation column.

For the structure of the display panel after the first electrode layer is formed, reference may be made to FIGS. 3 and 4.

In the preparation method for a display panel of this embodiment, the partition insulating portion is formed on at least one of the first side portion of the isolation column facing the hole region or the second side portion of the isolation column facing away from the hole region so that the first electrode layer cannot be in contact with the isolation column on at least one of the first side portion or the second side portion, the first electrode layer is completely partitioned, and a lateral conductive path cannot be formed in the non-display region. In this manner, even if static electricity is introduced into the hole region, the static electricity cannot enter the display region through the non-display region, thereby avoiding the generation of black spots on the display.

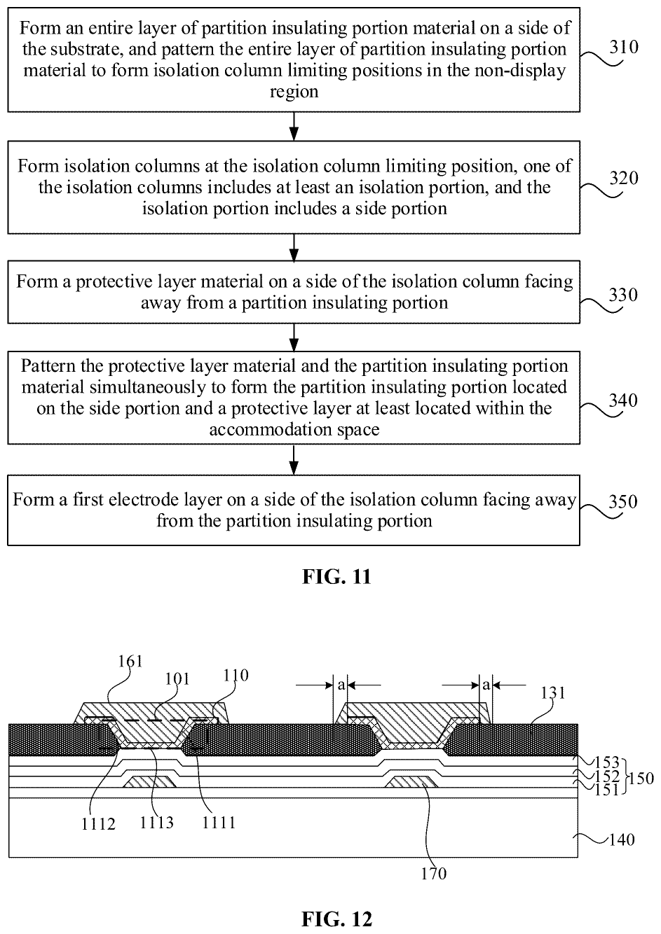

Referring to FIG. 10, for example, the isolation portion 111 further includes the bottom 1113 and the accommodation space surrounded by the bottom 1113, the first side portion 1111, and the second side portion 1112. A side of the bottom 1113 facing away from the display region (that is, a side facing the hole region FA) is connected to the first side portion 1111, and a side of the bottom facing the display region (that is, a side facing away from the hole region FA) is connected to the second side portion 1112. FIG. 11 is a flowchart of another preparation method for a display panel according to an embodiment of the present application. Referring to FIG. 11, the preparation method for a display panel includes the steps described below.

In step 310, an entire layer of partition insulating portion material is formed on a side of the substrate, and the entire layer of partition insulating portion material is patterned to form isolation column limiting positions in the non-display region. This step is the same as step 210 in the preceding embodiment, and the details are not repeated here.

In step 320, isolation columns are formed at the isolation column limiting positions, where one of the isolation columns includes at least an isolation portion, and the isolation portion includes a side portion. This step is the same as step 220 in the preceding embodiment, and the details are not repeated here.

In step 330, a protective layer material is formed on a side of the isolation column facing away from a partition insulating portion.

For example, since multiple preparation processes are further included after the isolation column is formed, if the isolation column is not protected, the surface of the isolation column may be corroded and collapse. In this embodiment, the protective material is formed on a side of the isolation column facing away from the partition insulating portion so that the surface of the isolation column can be effectively protected during the subsequent preparation processes, thereby preventing the isolation column from collapsing.

FIG. 12 is a schematic diagram of a middle structure of a display panel after a protective layer material is formed. Referring to FIG. 12, for example, when a protective layer material 161 is formed on a side of the isolation column 110 facing away from the partition insulating portion 130, the edge of the orthographic projection of the protective layer material on the substrate 140 extends beyond the edge of the orthographic projection of the corresponding isolation column 110 on the substrate 140 by at least 0.2 microns (the distance is the first distance a in the figure) so that the protective layer material covers both the surface of the isolation column 110 facing away from a partition insulating portion material 131 and the surface connected to the partition insulating portion material, that is, the protective layer material and the partition insulating portion material cover the entire isolation column 110, thereby protecting the entire isolation column 110.

In step 340, the protective layer material and the partition insulating portion material are patterned simultaneously to form the partition insulating portion located on the side portion and a protective layer at least located within the accommodation space.

The protective layer material and the partition insulating portion material are patterned simultaneously so that the preparation process of the display panel is relatively simplified.

In step 350, a first electrode layer is formed on a side of the isolation column facing away from the partition insulating portion. This step is the same as step 240 in the preceding embodiment, and the details are not repeated here.

In other example embodiments of the present application, before the entire layer of partition insulating portion material is formed, the following may further be included: forming the raising block 170 (referring to FIG. 12), the raising block 170 and the films in the display region of the display panel may be prepared in the same preparation process. When the isolation column 110 is formed subsequently, the isolation column 110 is formed at a corresponding position of the raising block 170, thereby increasing the relative height of the isolation column 110.

What is claimed is:

1. A display panel, comprising a display region and a non-display region;
a substrate;
a first electrode layer disposed on the substrate; and
at least an isolation column disposed on the substrate, the at least an isolation column being located between the substrate and the first electrode layer, being disposed in the non-display region, and the first electrode layer being partitioned by the at least an isolation column;
wherein an isolation column of the at least an isolation column at least comprises an isolation portion, the isolation portion comprises a side portion, and the side portion is provided with a partition insulating portion to insulate the side portion from the first electrode layer.

2. The display panel of claim 1, wherein the side portion comprises a first side portion facing away from the display region and a second side portion facing the display region, the isolation portion further comprises a bottom and an accommodation space at least formed by the bottom, the first side portion, and the second side portion, a side of the bottom facing away from the display region is connected to the first side portion, and a side of the bottom facing the display region is connected to the second side portion.

3. The display panel of claim 2, wherein a cross section of the accommodation space is an inverted trapezoid in a stacking direction of the display panel.

4. The display panel of claim 2, further comprising a hole region, wherein the non-display region surrounds at least part of the hole region, and the isolation column surrounds the hole region.

5. The display panel of claim 2, wherein the isolation column further comprises a first edge portion and a second edge portion, the first edge portion is connected to an end of the first side portion facing away from the substrate, and the second edge portion is connected to an end of the second side portion facing away from the substrate.

6. The display panel of claim 5, wherein the display panel satisfies at least one of the following:
an orthographic projection of the first edge portion and the first side portion on the substrate is a first orthographic projection, and a distance between inner and outer contours of the first orthographic projection is greater than or equal to 3 microns; or
an orthographic projection of the second edge portion and the second side portion on the substrate is a second orthographic projection, and a distance between inner and outer contours of the second orthographic projection is greater than or equal to 3 microns.

7. The display panel of claim 6, wherein an orthographic projection of the partition insulating portion on the substrate is located within an orthographic projection of the isolation column on the substrate.

8. The display panel of claim 5, further comprising a protective layer located at least within the accommodation space.

9. The display panel of claim 8, wherein the protective layer is further located on at least one of the following: a side of the first edge portion facing away from the substrate or a side of the second edge portion facing away from the substrate.

10. The display panel of claim 8, further comprising a plurality of insulating layers located in the display region and stacked between the substrate and the first electrode layer, wherein the plurality of insulating layers comprise a first planarization layer, a second planarization layer, a pixel defining layer, and a support column;
wherein the partition insulating portion is disposed in a same layer as any one of the plurality of insulating layers.

11. The display panel of claim 2, further comprising a raising block disposed between the substrate and the isolation column, wherein an orthographic projection of the raising block on the substrate is located within an orthographic projection of the bottom on the substrate.

12. The display panel of claim 11, further comprising:
an interlayer insulating layer disposed between the raising block and the isolation column;
wherein a distance between at least part of a contour of the orthographic projection of the raising block on the substrate and an outer contour of the orthographic projection of the bottom on the substrate is less than or equal to twice a thickness of the interlayer insulating layer.

13. The display panel of claim 11, wherein the display panel satisfies at least one of the following:
a maximum distance between the first side portion and an interlayer insulating layer in a stacking direction of the display panel is greater than or equal to 0.6 microns and less than or equal to 3 microns; or
a maximum distance between the second side portion and the interlayer insulating layer in the stacking direction of the display panel is greater than or equal to 0.6 microns and less than or equal to 3 microns.

14. The display panel of claim 11, further comprising:
a gate layer, a capacitor layer, and a source-drain layer that are stacked; and
an active layer located on a side of the gate layer facing the substrate or facing away from the substrate;
wherein the raising block is in a same layer as one of the active layer, the gate layer, the capacitor layer, or the source-drain layer.

15. The display panel of claim 14, wherein the isolation column is in a same layer as one of the gate layer, the capacitor layer, or the source-drain layer, and the isolation column and the raising block are located in different layers; and
the isolation column is in a same layer as a metal layer located on a side of the source-drain layer facing away from the substrate.

16. The display panel of claim 15, further comprising a second electrode layer and a light-emitting material layer that are stacked between the source-drain layer and the first electrode layer, wherein the source-drain layer and the second electrode layer are electrically connected through a via connecting portion, and the metal layer is the via connecting portion.

17. The display panel of claim 1, wherein a thickness of the partition insulating portion is greater than a thickness of the first electrode layer.

18. The display panel of claim 10, wherein the protective layer is in a same layer as the second planarization layer.

19. A display panel, comprising a display region and a non-display region;
a substrate;
a first electrode layer disposed on the substrate; and
at least an isolation column disposed on the substrate, the at least an isolation column being located between the substrate and the first electrode layer, being disposed in the non-display region, an isolation column of the at least an isolation column at least comprising an isolation portion, the isolation portion comprising a side portion;
wherein the first electrode layer comprises a first portion and a second portion which are partitioned by the at least an isolation column, the first portion is located at one side of the at least an isolation column facing away from the substrate, the second portion is adjacent to the side portion in a direction from the display region to the non-display region; and
the side portion is provided with a partition insulating portion, and the second portion is insulated from the side portion.

20. A display device, comprising the display panel according to claim 1.
